(19) United States
(12) Patent Application Publication
(10) Pub. No.: US 2015/0156901 A1
(43) Pub. Date: Jun. 4, 2015

(54) INVERTER FOR ELECTRIC VEHICLE

(71) Applicant: LSIS CO., LTD., Anyang-si (KR)

(72) Inventors: SEUNG HUN LEE, Seoul (KR); KI YOUNG MOON, Cheonan-si (KR); SUNG JUN OH, Cheonan-si (KR)

(73) Assignee: LSIS CO., LTD., Anyang-si (KR)

(21) Appl. No.: 14/557,323

(22) Filed: Dec. 1, 2014

(30) Foreign Application Priority Data
Dec. 3, 2013 (KR) 20-2013-0009985

(51) Int. Cl. H05K 5/02; H05K 7/20

(52) U.S. Cl. CPC H05K 5/0217; H05K 7/2039

(57) ABSTRACT

Provided is an inverter for an electric vehicle. The inverter for the electric vehicle includes a heat sink, a power semiconductor module disposed on an upper portion of the heat sink, a control board connected to the power semiconductor module, a light source coupled to the control board, a case coupled to the upper portion of the heat sink to cover the power semiconductor module and the control board, and an indicator coupled to the case to transmit light emitted from the light source therethrough. The indicator is double injection-molded to the case.

### CROSS-REFERENCE TO RELATED APPLICATIONS

Pursuant to 35 U.S.C. §119(a), this application claims the benefit of earlier filing date and right of priority to Korean Patent Application No. 20-2013-0009985, filed on Dec. 3, 2013, the contents of which are hereby incorporated by reference herein in its entirety.

### BACKGROUND

The present disclosure relates to an inverter for an electric vehicle, and more particularly, to an inverter for an electric vehicle, which has an improved waterproof structure.

Recently, technologies with respect to electric vehicles using electricity that is green energy are being rapidly developed. Electric vehicles represent vehicles running by using electricity. Electric vehicles are largely classified into battery powered electric vehicles and hybrid electric vehicles. The battery powered electric vehicles that run by using only electricity are called electric vehicles. The hybrid electric vehicles represent vehicles running by using electricity and fossil fuels.

Electric vehicle engines used for most of electric vehicles rotate a motor by electricity supplied from a battery instead of a gasoline for a gasoline engine to generate rotational force of the motor. Then, the rotational force of the motor is reduced by a reducer to transmit the reduced rotational force to left and right driving wheels through a differential gear, thereby allowing the vehicle to run.

Accordingly, such an electric vehicle includes a motor generating rotational force, a battery supplying a power to the motor, an inverter controlling the number of revolution of the motor, a battery charger for electrically charging the battery, and a low voltage DC/DC converter (LDC) for vehicles.

Among them, the inverter senses whether high voltage current is well outputted to control the current.

FIG. 1 is a side cross-sectional view of a portion of an inverter for an electric vehicle according to the related art.

The inverter has one side that is covered by an inverter case 10. An indicator 20 formed of a transparent material that is capable of transmitting light is coupled to the case 10. A hole to which the indicator 20 is coupled is defined in the case 10, and a portion of the indicator 20 is inserted into and fixed to the hole.

Here, a coupling part between the indicator 20 and the case 10 should have a watertight structure that is capable of preventing water or foreign substances from passing therethrough. Thus, an O-ring 30 is inserted between the inside of the case 10 and the outside of the indicator 20. Also, a cover plate 40 having a plate shape is coupled to the inside of the O-rings.

Accordingly, to secure the watertight function of the portion to which the indicator 20 is coupled, additional components such as the O-ring 30 and the cover plate 40 are necessary. Also, it is necessary to perform a process in which the O-ring 30 is fitted outside the indicator 20, and then the cover plate 40 is coupled to the inside of the indicator 20.

Therefore, it is required to more simply realize the waterproof inverter.

### SUMMARY

Embodiments provide an inverter for an electric vehicle, which has an improved waterproof function through a simple structure by double injection-molding a case and an indicator.

In one embodiment, an inverter for an electric vehicle includes: a heat sink; a power semiconductor module disposed on an upper portion of the heat sink; a control board connected to the power semiconductor module; a light source coupled to the control board; a case coupled to the upper portion of the heat sink to cover the power semiconductor module and the control board; and an indicator coupled to the case to transmit light emitted from the light source therethrough, wherein the indicator is double injection-molded to the case.

The indicator may include a main body that vertically lengthily extends and a flange part protruding outward from the main body.

A protrusion protruding downward may be disposed on the case, the indicator may be disposed on a portion on which the protrusion is disposed, and the flange part may be disposed in the protrusion.

The indicator may be provided in plurality, and the case may include a blocking part in which a portion of a lower portion of the case further protrudes downward from the protrusion.

The blocking part protruding downward may be disposed on the protrusion, and the blocking part may be disposed between one indicator and the other indicator.

The indicator may have an upper end exposed to an upper side of the case.

The details of one or more embodiments are set forth in the accompanying drawings and the description below. Other features will be apparent from the description and drawings, and from the claims.

### BRIEF DESCRIPTION OF THE DRAWINGS

FIG. 1 is a side cross-sectional view illustrating a portion of an electric vehicle inverter according to the related art.

FIG. 2 is a side cross-sectional view of an inverter according to an embodiment.

FIG. 3 is a partial enlarged view of the inverter of FIG. 2.

FIG. 4 is a bottom view of the inverter of FIG. 3.

FIG. 5 is a perspective view of the indicator.

### DETAILED DESCRIPTION OF THE EMBODIMENTS

Hereinafter, an electric vehicle inverter according to an embodiment will be described with reference to the attached drawings.

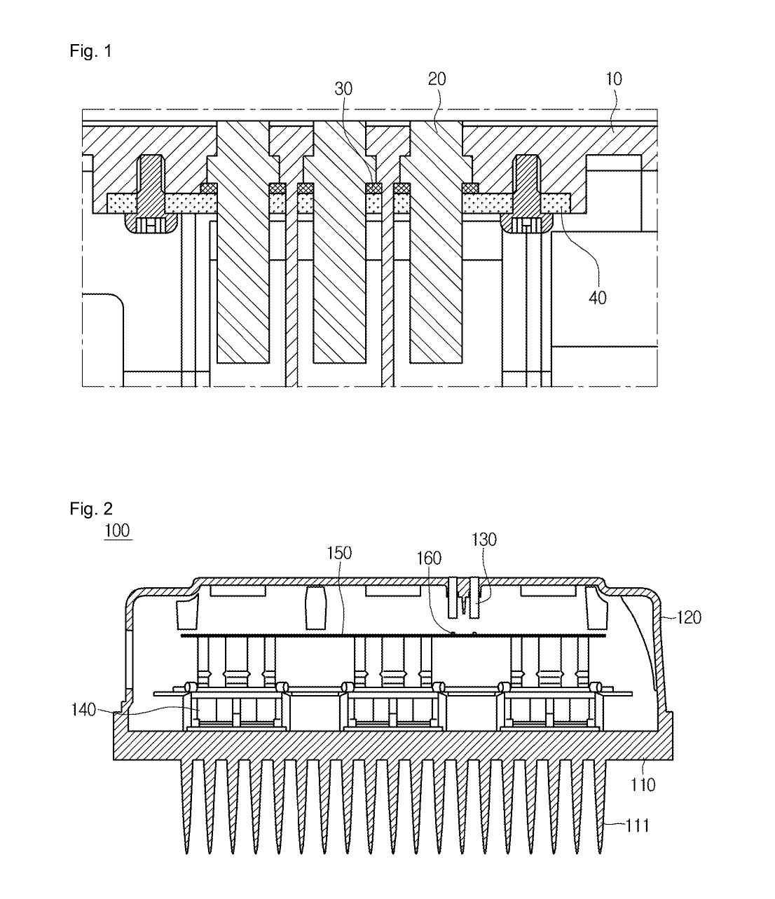

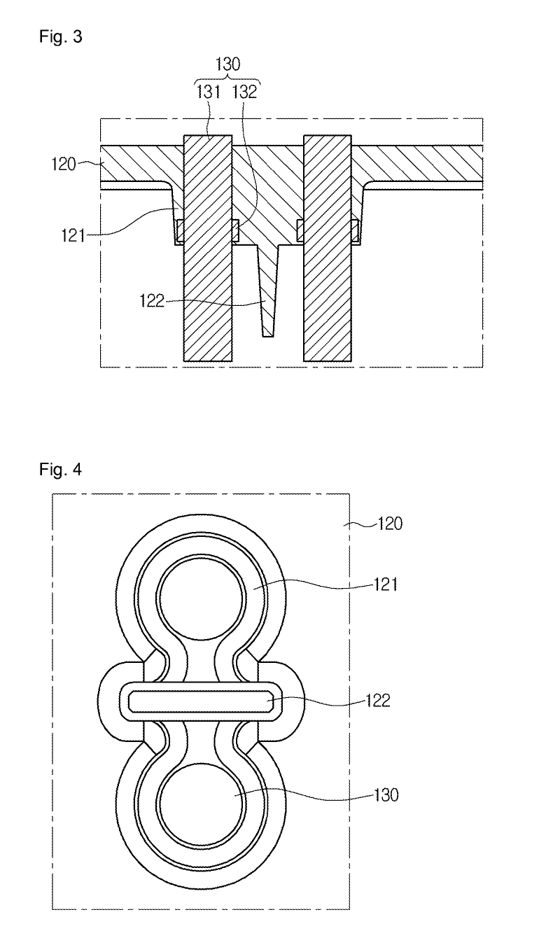

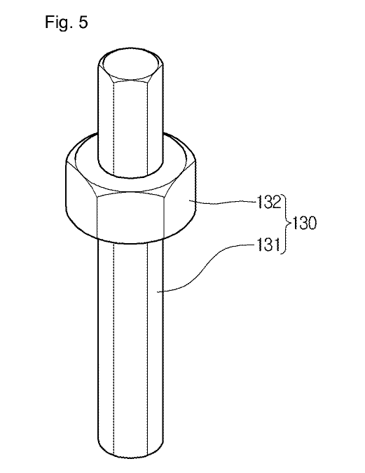

FIG. 1 is a side cross-sectional view illustrating a portion of an electric vehicle inverter according to the related art, FIG. 2 is a side cross-sectional view of an inverter according to an embodiment, FIG. 3 is a partial enlarged view of the inverter of FIG. 2, FIG. 4 is a bottom view of the inverter of FIG. 3, and FIG. 5 is a perspective view of the indicator.

An inverter for an electric vehicle according to an embodiment includes a heat sink 110, a power semiconductor module 140, a control board 150 connected to the power semiconductor module 140, a light source 160 coupled to the control board 150, a case 120 connected to an upper portion of the heat sink 110 to cover the power semiconductor module 140 and the control board 150, and an indicator 130 coupled to the case 120.

Firstly, the heat sink 110 is formed of a material having superior thermal conductivity to emit heat generated from the power semiconductor module. That is, the heat sink may be formed of aluminum or aluminum alloy having superior thermal dissipation properties. A plurality of heat dissipation fins 111 is disposed on a lower portion of the heat sink 110 to increase a heat dissipation area, thereby improving heat dissipation performance.

The power semiconductor module 140 may include transistors of which an on/off operation is controlled by an external signal, diodes having rectifying characteristics, and other devices. Here, general transistors may include MOSFET, IGBT, etc.

The control board 150 includes a printed circuit board (PCB) and a plurality of semiconductor devices mounted on the PCB. The semiconductor devices mounted on the PCB may include both of active devices and passive devices.

The light source 160 is coupled to the control board 150. A light emitting diode (LED) or an infrared lamp may be used as the light source 160. If it is capable of emitting light, the present disclosure is not limited to kinds of light sources. The light source 160 may be connected to the control board 150 to display an operation state of the inverter. The light source 160 may include a plurality of LEDs emitting light having colors different from each other.

The case 120 has an edge that is bent downward to extend. In addition, the case 120 is coupled to an upper portion of the heat sink 110 to accommodate the power semiconductor module 140 and the control board 150 therein. Accordingly, the power semiconductor module 140 and the control board 150 are disposed in an inner space surrounded by the heat sink 110 and the case 120.

As illustrated in FIG. 3, the case 120 includes a protrusion 121 in which a portion of the case 120 protrudes downwardly. A portion having a predetermined area of the case 120 protrudes downward to form the protrusion 121.

Also, the case 120 may further include a blocking part 122 that further extends downward from the protrusion 121. The blocking part 122 is disposed between a plurality of indicators 130 that will be described later. That is, the blocking part 122 is disposed between one indicator 130 and the other adjacent indicator 130 to prevent light passing through one indicator 130 from entering into the other indicator 130. Thus, the blocking part 122 may have a plate shape of which one surface faces to one indicator 130 and the other surface faces the other indicator 130.

The case 120 may be formed of a poly-butylene-terephthalate fiber (PBT), poly carbonate (PC) or glass fiber composite in consideration of stiffness, temperature condition, and the like.

The indicator 130 may be formed of a light-transmittable material, i.e., a transparent material. For example, the indicator 130 may be formed of an acrylic material.

The indicator 130 includes a main body 131 that vertically lengthily extends in a cylindrical or polygonal pillar shape and a flange 132 protruding outward from the main body 131. Thus, the flange 132 has a diameter or planar area greater than that of the main body 131 and a vertical length less than that of the main body 131. In other words, the flange 132 protrudes in a direction perpendicular to the length direction of the main body 131.

The flange 132 is disposed to be biased upward from a vertical center of the main body 131. That is, the flange 132 is coupled to a portion that is biased somewhat upward from an exact center of the main body 131.

Alternatively, the indicator 130 may be integrally provided. That is, the main body 131 and the flange 132 may be integrated with each other.

The indicator 130 may be provided in plurality to transmit light having colors different from each other according to a color of the light source 160.

Here, even though the light having colors different from each other is transmitted through the plurality of indicators 130, since the blocking part 122 blocks the light between the plurality of indicators 130, the light emitted from the light source 160 may not be transmitted into the other adjacent indicator 130 except for the corresponding indicator 130.

The case 120 is double injection-molded together with the indicator 130. That is, when the case 120 is molded, the injection molding may be performed after the pre-molded indicator 130 is disposed inside a mold. Thus, sealing between the indicator 130 and the case 120 may be perfectly maintained to prevent water from leaking or foreign substances from being introduced through the coupled portion between the indicator 130 and the case 120.

The indicator 130 is disposed in the protrusion 121 of the case 120. Here, a portion of an upper portion of the indicator 130 is disposed inside the case 120. In more detail, a portion of an upper portion of the indicator 130 including the flange 132 is embedded in the protrusion 121. Thus, a portion of a lower portion of the indicator 130 that is not embedded in the protrusion 121 may be exposed to the outside of the protrusion 121 to extend downward.

Here, an upper end of the indicator 130 is exposed upward. Thus, the indicator 130 may be observed from an upper side of the case 120, and also light emitted through the indicator 130 may be seen.

According to the above-described structure, even though the O-ring and the cover plate which are used for watertight inverter according to the related art are removed, the superior watertight performance may be maintained.

Also, since the number of parts is reduced, and the manufacturing process is simplified, the manufacturing costs may be reduced.

According to the embodiment, the waterproof function of the inverter for the electric vehicle may be easily improved, and the assembling process may be simplified to reduce the manufacturing costs.

Although embodiments have been described with reference to a number of illustrative embodiments thereof, it should be understood that numerous other modifications and embodiments can be devised by those skilled in the art that will fall within the spirit and scope of the principles of this disclosure.

The disclosure may, however, be embodied in many different forms and should not be construed as being limited to the embodiments set forth herein. Rather, these embodiments are provided so that this disclosure will be thorough and complete, and will fully convey the concept of the invention to those skilled in the art.

Therefore, the scope of the disclosure is defined not by the detailed description of the invention but by the appended claims. Further, the appended claims should be appreciated as a step including even another embodiment.

What is claimed is:

1. An inverter for an electric vehicle, the inverter comprising:
a heat sink;
a power semiconductor module disposed on an upper portion of the heat sink;
a control board connected to the power semiconductor module;
a light source coupled to the control board;
a case coupled to the upper portion of the heat sink to cover the power semiconductor module and the control board; and
an indicator coupled to the case to transmit light emitted from the light source therethrough,
wherein the indicator is double injection-molded to the case.

2. The inverter according to claim 1, wherein the indicator comprises:
a main body that vertically lengthily extends; and
a flange part protruding outward from the main body.

3. The inverter according to claim 2, wherein a protrusion protruding downward is disposed on the case,
the indicator is disposed on a portion on which the protrusion is disposed, and
the flange part is disposed in the protrusion.

4. The inverter according to claim 3, wherein the indicator is provided in plurality, and
the case comprises a blocking part in which a portion of a lower portion of the case further protrudes downward from the protrusion.

5. The inverter according to claim 4, wherein the blocking part protruding downward is disposed on the protrusion, and
the blocking part is disposed between one indicator and the other indicator.

6. The inverter according to claim 4, wherein the indicator has an upper end exposed to an upper side of the case.

7. An inverter for an electric vehicle, the inverter comprising:
a heat sink;
a power semiconductor module disposed on an upper portion of the heat sink;
a control board connected to the power semiconductor module;
a light source coupled to the control board;
a case coupled to an upper portion of the heat sink to cover the power semiconductor module and the control board; and
an indicator coupled to the case, the indicator being disposed above the light source,
wherein the indicator is provided in plurality, and
a blocking part extending from the case is disposed between the indicators.

8. The inverter according to claim 7, wherein the indicator comprises:
a main body that vertically lengthily extends; and
a flange part protruding in a direction perpendicular to a length direction of the main body.

9. The inverter according to claim 7, wherein a protrusion protruding downward is disposed on the case, and
the blocking part extends from the protrusion towards the light source.
